(19) United States
(12) Patent Application Publication
(10) Pub. No.: US 2014/0137925 A1
(43) Pub. Date: May 22, 2014

(54) SELF-LEVELING AND SELF-ALIGNING SOLAR PLATFORM

(71) Applicant: Ameristar Solar, LLC, Banks, OR (US)

(72) Inventor: Sidney William Boyk, Banks, OR (US)

(21) Appl. No.: 13/839,796

(22) Filed: Mar. 15, 2013

Related U.S. Application Data
(60) Provisional application No. 61/727,541, filed on Nov. 16, 2012.

(51) Int. Cl. H01L 31/042

(52) U.S. Cl. CPC H01L 31/0422
USPC 136/246

(57) ABSTRACT

A mobile solar platform has at least one solar panel, the solar panel having an electrical connection to power storage, a pivotable center chord attached to the solar panel to allow the panel to rotate, a movable truss supporting the solar panel and the chord, and at least two outriggers to support the truss.

### RELATED APPLICATIONS

This application claims priority to U.S. Provisional Patent Application No. 61/727,541, filed Nov. 16, 2012 and is incorporated herein in its entirety.

### BACKGROUND

Portable electric power requirements, the need for electrical power away from any traditional source of power, present many challenges. Typically, portable power consumers turn to generators, which require some source of fuel such as gasoline, diesel, JP4, etc. In order to provide sufficient power to any significant group or structure, such as remote research stations, military command posts and other support groups, these generators reach rather large sizes. Usually, large trucks or other heavy duty vehicles tow the generators and their accompanying fuel supply to the destination.

In operation, generators are typically noisy, create fumes, require careful placement and concealment, etc. The fuel needs to be replenished regularly for deployments or other uses beyond a few days. This also adds to the expense, as not only does fuel need to be supplied to the generator, it also is needed to fuel the trucks that bring the fuel.

The advent of solar panels and their use in remote locations have brought several advantages. However, due to the materials from which they are made, the larger solar panels needed to generate significant power do not necessarily travel well. They are somewhat brittle and made from materials that can easily scratch or crack. These defects lower the efficiency of the panels as they affect the amount of sunlight that reaches the photovoltaic (PV) cells in the panels.

### BRIEF DESCRIPTION OF THE DRAWINGS

FIG. 1 shows an embodiment of a mobile solar platform.

FIG. 2 shows a more detailed view of an embodiment of a mobile solar platform.

FIG. 3 shows an end view of a mobile solar platform.

FIG. 4 shows an end view of a mobile solar platform in a deployed configuration.

FIG. 5 shows a side view of a mobile solar platform in a shipping configuration.

FIG. 6 shows a side view of an alternative embodiment of a mobile solar platform in a shipping configuration.

FIG. 7 shows a side view of an embodiment of a larger mobile solar platform.

FIG. 8 shows a mobile solar platform having mounting blocks.

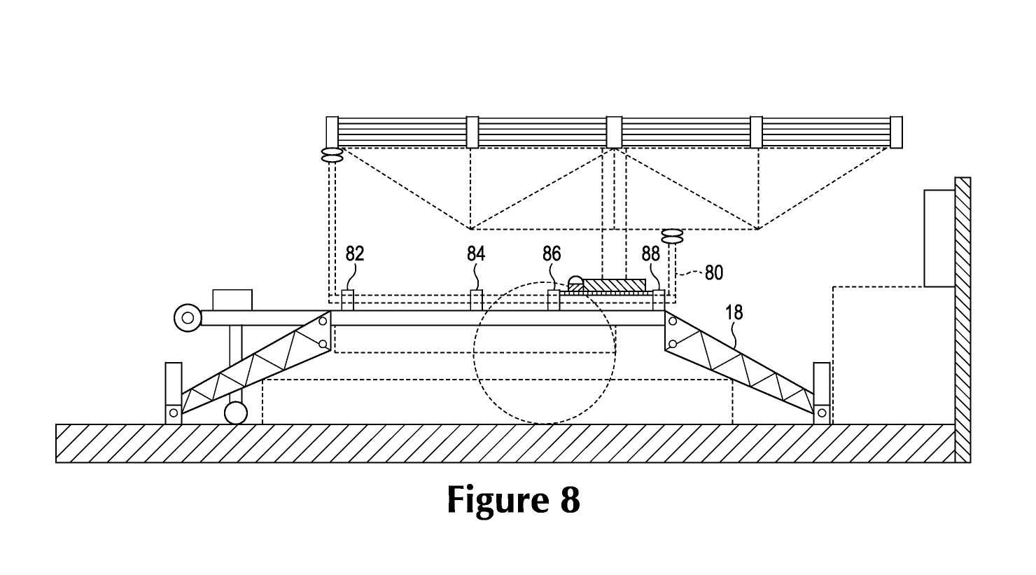

### DETAILED DESCRIPTION OF THE EMBODIMENTS

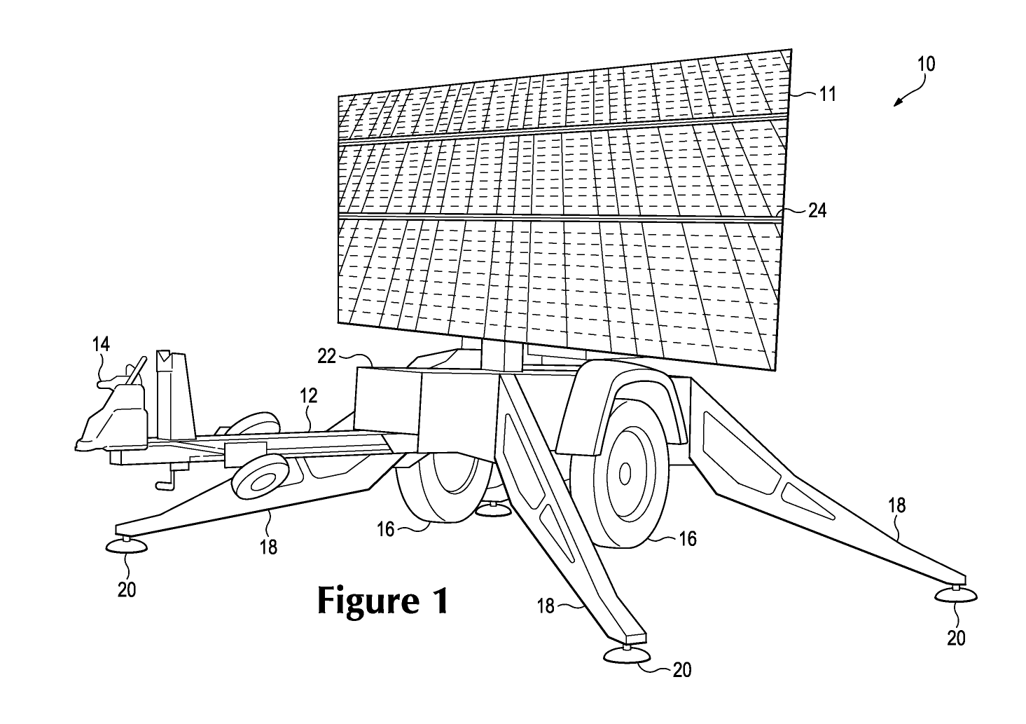

FIG. 1 shows a mobile platform 10 for solar panels. Many of the examples discussed here exist in a military context, with the understanding that these are just examples and that minor adaptations to non-military specifications, or the use of the military-specified examples in many other contexts, are within the embodiments. No limitation to any specific dimensions, uses or environments is intended, nor should any be inferred.

The platform consists of a trailer body 12 having a trailer ball receiver 14 for a connection to a typical trailer hitch. In an alternative embodiment, the trailer tongue uses a standard 3″ military pintle hook and eye. The trailer body 12 has standard-sized tires such as 16, making for easy replacement. In this embodiment they are 37″ military tires. The trailer body has 16-18″ of ground clearance, allowing transportation across rough terrain. In other applications, the tires, wheels, and axels may be removable to move them out of the way.

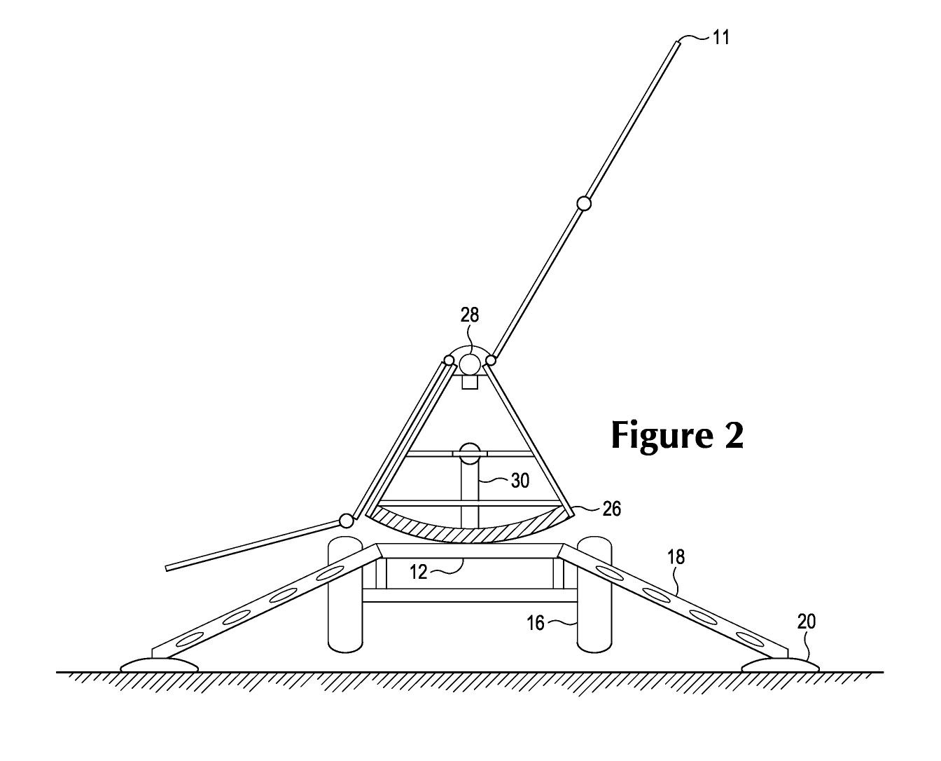

Once in place, the trailer has outriggers such as 18, having adjustable feet such as 20. These outriggers are hydraulic and remotely controllable. The control box 22 may include an interface control board (not shown) and a radio frequency, Bluetooth®, or other remote communications capability, allowing the outriggers to be lowered and raised from within another vehicle. This interface will also typically allow remote control of the positioning of the solar panels, as will be discussed in FIG. 2.

The array of solar panels such as 11 has shock absorbers such as 24 between them to prevent damage to the panels while being transported. The material used may be any material that provides a union or a joint between the panels that also allows for shock absorption. In order to lock the panels into place, the material may be rigid rather than flexible. The points of contact between the solar panel array and the trailer will also have some sort of shock absorbency to further ensure the safety of the panels. The back side of the panels, opposite to the side shown in FIG. 1, may consist of bullet proof materials. For military environments, there may be some sort of covering or honeycombed structure in place over the panels themselves to reduce glare and detectability.

The array of panels is mounted on a self-leveling truss, shown in more detail in FIG. 2. The panels couple to the trailer/towing assembly through a top cord 28, shown in end view in FIG. 2. In this embodiment, the top cord consists of a hinged coupler for rotating the panels into a solar facing configuration in one of many angles as shown. The top cord flexible assembly allows panels to stow and fold in both directions in excessive wind conditions. The top cord may also house a retractable reel that unwinds an adjustable foam cushion between panels to prevent glass damage during transport.

As mentioned previously, the control of the rotation may come from a communications interface that resides in the control box 22 of FIG. 1, or within the space frame 30, shown in FIG. 2. The self-leveling truss 26 mounts to the trailer body through a hydraulic gear 26 that allows the ‘turret’ to pan and tilt for the most efficient positioning of the solar panels.

Having discussed the overall configuration and capabilities of the mobile solar platform, with self-leveling and self-alignment, the discussion now moves to the capabilities. The control box or the space frame of the trailer body can support many different types of outlets, such as 24 volts direct current (VDC) and 120 volts alternating current (VAC). Further, for military application, where certain equipment uses rechargeable lithium-ion (Li-ON) batteries and ultra-capacitors, further connectors may be provided for their recharging, even while still in the vests worn by personnel using the battery-powered equipment such as night vision goggles, etc.

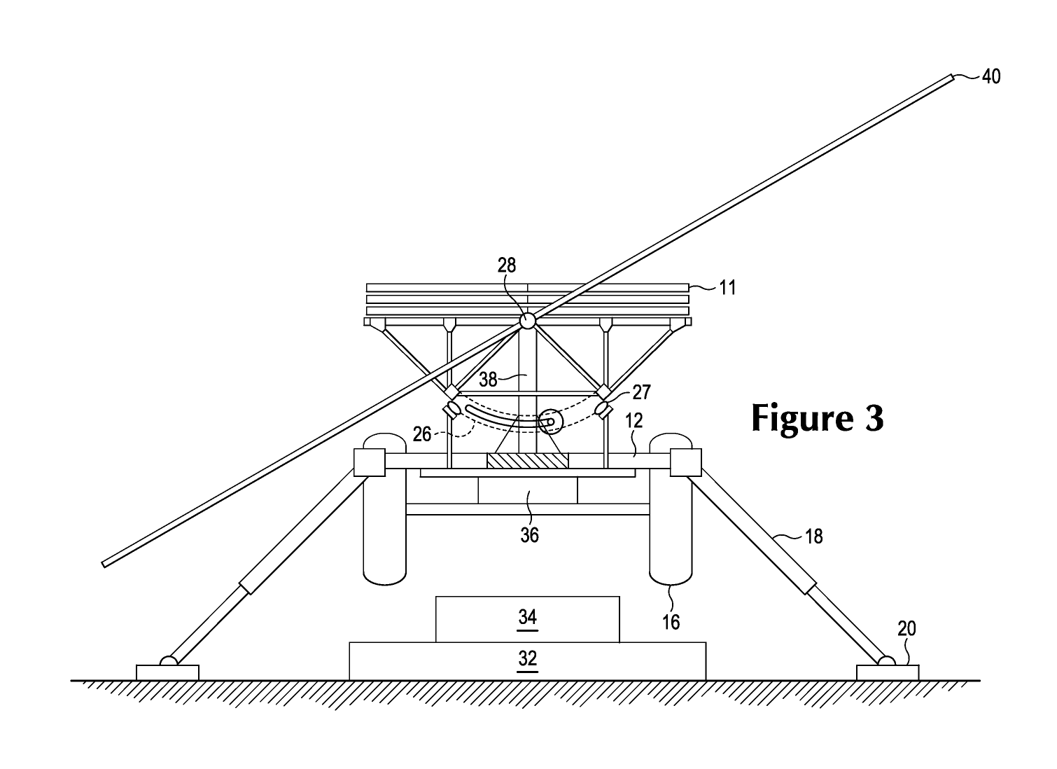

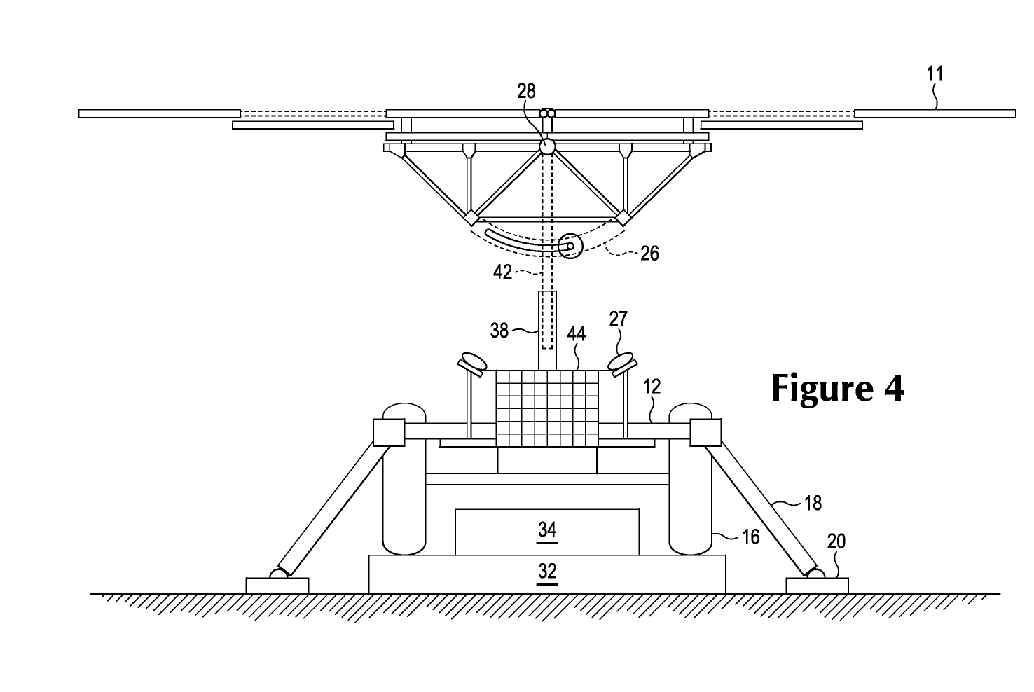

FIG. 3 shows an end view of an embodiment of a mobile solar platform 10. The trailer body 12 supports the movable truss 26 that in turn supports the solar panels 11. The solar panels are stackable as shown, or deployable into a large array of panels. The truss 26 allows the array of panels to deploy as shown by position 40. The solar panels such as 11 move to form an array of solar panels that can rotate about the center chord 28. The truss 26 is cushioned by air bags or other shock absorbers 27. The solar panel array may be supported by a center cylinder 28, alternative to the embodiment of FIG. 2. This will be discussed in more detail with regard to FIG. 4.

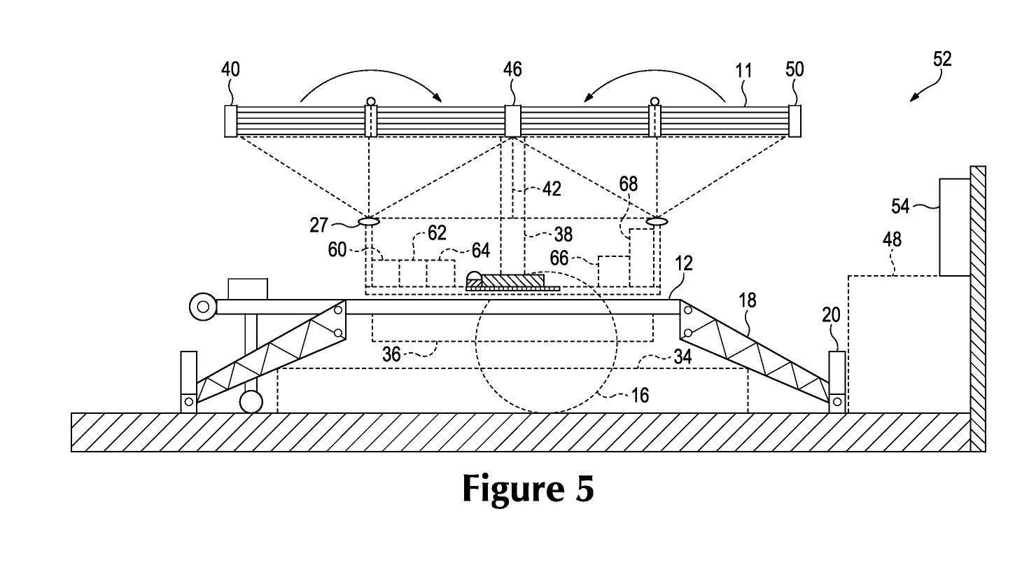

The mobile solar platform will generally have at least one power storage to which the solar panels are electrically connected. In the embodiment of FIG. 3, a first battery back 36 may store enough power for 3 days and a second battery pack 34 may store enough power for 7-10 days. The mobile solar platform shown may have the outriggers such as 18 and feet 20 set out to hold the trailer body 12, or it may rest on the tires 16. Alternatively the outriggers may be used to stabilize the platform, and the tires may rest on a flat rack such as 32, as shown in FIG. 4 and discussed in more detail in FIG. 5.

In FIG. 4, the center post 38 is shown to be a hydraulic cylinder with a center post 42. When extended, the cylinder allows the solar panel array to achieve heights that may allow the solar panels to receive more sunlight than if not extended. As shown in FIG. 4, the solar panels such as 11 are ‘unstacked’ or deployed into an array of solar panels. The stacking of the panels allows for easy transport on the trailer, especially in field conditions such as those experienced by the military, relief and aid organizations such as the Red Cross® or the Federal Emergency Management Agency (FEMA). The mobile solar platform may provide power for water sterilization components such as an LED-based water purification system 44 that uses ultraviolet LEDs to purify water. In addition, while in transport, top panels provide a trickle charge to batteries or capacitors.

When used in the field, the trailer will be transported on the tires, typically towed behind a truck or other vehicle. However, as shown in FIG. 5, the mobile solar power platform may have dimensions that allow it to be shipped in a standard ISO container 52. The container may be equipped with a flatrack 32 that allows the trailer to slide out of the container when the track is activated by controls 54. The trailer may also have dimensions to allow a generator 48 to be packed with the mobile solar platform, allowing packaging of the power components for an organization in the same container.

Also, as mentioned above, the solar panels are stackable for transport. The solar panels have attachments such as rollers such as 40 and 50 or double rollers 46 that allow the panels to separate and deploy into a larger array of solar panels. This allows the panels to be stacked and the mobile solar platform made more compact for shipment and travel, while providing cushioning between the panels and the supporting structure to avoid breaking of the panels.

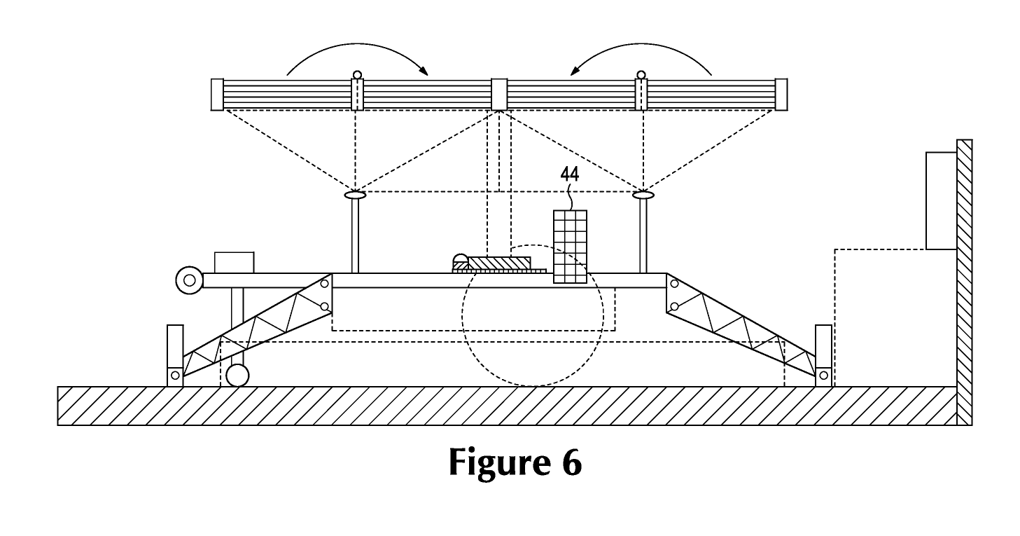

Also shown in FIG. 5 are several more configurations of battery packs such as 60, 62, 64, 66 and 68. These battery packs may store power for uses adjacent the mobile solar platform or they may be removable batteries used for field equipment, such as hand-held radios, night vision goggles or helmets, other communication or tracking devices, etc. FIG. 6 shows a side view of a mobile solar platform having the water purification system 44 in lieu of the battery packs, but a platform may contain both.

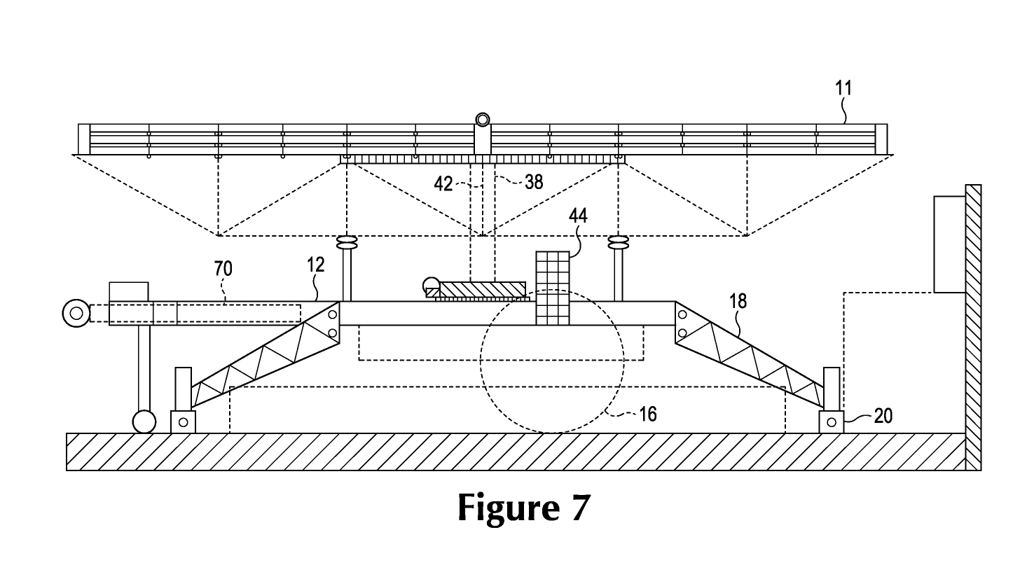

Up to this point, the discussion has focused on a relatively small version of the mobile solar platform. For example, one embodiment deploys 24 solar panels. The small version of the mobile solar platform fits on a standard military trailer such as the M1101 or the M1102. In the previous embodiments to FIG. 7, the trailer 12 consists of such a trailer or a like-sized trailer.

FIG. 7 shows an embodiment of a mobile solar platform of larger size. In this embodiment, the platform deploys 36 panels, 18 of which are seen in the side view, with another 18 on the opposite side. This larger platform will typically require trailer 12 to be larger as well. In addition, the trailer may have an extendable or telescoping tongue 70. The telescoping tongue allows the trailer hitch/pintle extend beyond the bottom of the panel to reach a trailer hitch on a towing vehicle. Most of the components may have larger sizes to allow for the longer and heavier solar panel array. The center post 38 and its telescoping cylinder 42 may be wider and have stronger hydraulics. Similarly, the tires 16 may be larger than those used on the smaller version of the trailer, the outriggers 18 may be longer and the feet 20 larger.

One should note that the outriggers 18 may attach to the trailer. In this embodiment, the towing vehicle tows the trailer into place, and the outriggers are extended and locked into place to stabilize the platform. The towing vehicle then drives away, leaving the trailer behind. In an alternative scenario, the outriggers are attached to the mobile solar platform, and the platform 80 is connected to the trailer by mounting blocks such as 82, 84, 86 and 88. Typically, the mounting blocks will have corresponding blocks on the other side of the platform. This allows the towing vehicle to position the trailer in a manner that allows proper positioning of the mobile solar platform. The mounting blocks are then disengaged and the outriggers deployed. When the outriggers have raised the platform high enough off the trailer bed, the towing vehicle can drive away with the vehicle still attached.

As can be seen from the above, there are numerous variations and embodiments that all fall within the scope of these embodiments. Different variations and modifications from different embodiments above may be combined with other variations and modifications of other embodiments. No restriction of any particular accessory or configuration to any particular embodiment is intended nor should any be implied.

In this manner, a mobile solar platform suitable for easy shipment, towing and deploying is provided. The mobile solar platform may provide power for tactical, relief and aid environments with no requirements for external power. Further adaptations to the configuration and the uses of the solar power may result in further modifications and variations to the solar platform.

It will be appreciated that several of the above-disclosed and other features and functions, or alternatives thereof, may be desirably combined into many other different systems or applications. Also that various presently unforeseen or unanticipated alternatives, modifications, variations, or improvements therein may be subsequently made by those skilled in the art which are also intended to be encompassed by the embodiments.

What is claimed is:

1. A mobile solar platform, comprising:
at least one solar panel, the solar panel having an electrical connection to power storage;
a pivotable center chord attached to the solar panel to allow the panel to rotate;
a movable truss supporting the solar panel and the chord; and
at least two outriggers to support the truss.

2. The mobile solar platform of claim 1, further comprising a center support column between the movable truss and the pivotable center chord.

3. The mobile solar platform of claim 2, wherein the center support column comprises a hydraulic cylinder having an extendable center column.

4. The mobile solar platform further comprising a trailer body supporting the movable truss.

5. The mobile solar platform of claim 1, the trailer body having tires.

6. The mobile solar platform of claim 1, wherein the at least one solar panel comprises multiple solar panels.

7. The mobile solar platform of claim 6, wherein the solar panels are stackable and extendable.

8. The mobile solar platform of claim 7, wherein the solar panels include roller attachments that allow the panels to extend from a stacked configuration.

9. The mobile solar platform of claim 1, wherein the electrical connection to power storage comprises a connection to at least one battery pack.

10. The mobile solar platform of claim 9, wherein the at least one battery pack comprises a battery pack that stores enough power for three days.

11. The mobile solar platform of claim 9, wherein the at least one battery pack comprises a battery pack that stores enough power for at least seven days.

12. The mobile solar platform of claim 1, further comprising shock absorbers between the truss and the solar panel.

13. The mobile solar platform of claim 1, the solar panel having dimensions that allow the mobile platform to fit into an ISO container.

14. The mobile solar platform of claim 13, the ISO container having a flat rack inside to which the mobile solar platform can be attached.

15. The mobile solar platform of claim 14, wherein the flat rack has rollers to allow the mobile solar platform to slide out of the container.

16. The mobile solar platform of claim 1, wherein the outriggers attach to the mobile solar platform.

17. The mobile solar platform of claim 1, wherein the outriggers attached to a trailer upon which the mobile solar platform is mounted.
